(19) United States
(12) Patent Application Publication
(10) Pub. No.: US 2009/0259603 A1
(43) Pub. Date: Oct. 15, 2009

(54) MOBILE INTELLIGENT METERING AND CHARGING SYSTEM FOR CHARGING UNIQUELY IDENTIFIABLE CHARGEABLE VEHICLE DESTINATIONS AND METHOD FOR EMPLOYING SAME

(75) Inventors: Richard Housh, Columbus, OH (US); Benjamin Joseph Yurkovich, Columbus, OH (US)

Correspondence Address: GALLAGHER & DAWSEY CO., L.P.A., P.O. BOX 785, COLUMBUS, OH, 43216, US

(73) Assignee: JUICE TECHNOLOGIES, INC.

(21) Appl. No.: 12/277,617

(22) Filed: Nov. 25, 2008

Related U.S. Application Data
(60) Provisional application No. 61/123,701, filed on Apr. 10, 2008.
(60) Provisional application No. 61/086,265, filed on Aug. 5, 2008.

(51) Int. Cl. G06F 1/26; G06F 17/00

(52) U.S. Cl. 705/412; 700/295

(57) ABSTRACT

The instant invention relates to a mobile intelligent metering and charging system for charging uniquely identifiable chargable vehicle destinations (V) and method for employing the same. The system includes at least a power distribution system limb and a power consumption control and recordation limb. A vehicle system meter and at least one programmable command and control system identify unique vehicles, batteries, user accounts or other predetermined locations for charging and accounting purposes. Both the at least one programmable command and control system and the vehicle system meter are in communication with both the power distribution system limb and the power consumption control and recordation limb, and the at least one programmable command and control system controls the transmission of power through the vehicle system meter according to a predetermined and programmable algorithm, resulting in charging of the uniquely identifiable chargable vehicle destination.

### RELATED APPLICATIONS

This application claims the benefit of U.S. provisional patent application Ser. No. 61/123,701; filed Apr. 10, 2008; and U.S. provisional patent application Ser. No. 61/086,265; filed Aug. 5, 2008; all of which are incorporated by reference as if completely written herein.

### STATEMENT REGARDING FEDERALLY SPONSORED RESEARCH OR DEVELOPMENT

This invention was not made as part of a federally sponsored research or development project.

### TECHNICAL FIELD

The instant invention relates to a mobile intelligent metering and charging system for charging uniquely identifiable chargable vehicle destinations and a method for employing the same.

### BACKGROUND OF THE INVENTION

With automotive manufacturer's plans to release electric vehicles and plug-in hybrid electric vehicles onto the streets, utility companies must plan for a significant load addition to the electric power grid. This load is a concern to utility companies because it means that there will be increased load on the utility grid, which may add additional stress to an already overloaded power grid. Some of this stress can be avoided by moving some of the large loads to off-peak hours. To motivate operators of electric vehicles to charge their vehicles during these off-peak hours, special tariffs, taxes (including possibly tax credits), and electrical usage rates may be placed for charging electric vehicles, especially at certain times.

Traditionally, electric power is priced on a demand basis, resulting in higher electric power costs during peak use, which generally occurs in the daytime, and lower electric power costs during off-peak use, which generally occurs at night. This means that if electric vehicles could be charged during off-peak hours, it would help both the utility and the consumer by diverting electrical usage in the vehicle charging process to off peak hours. This will allow utility companies to sell electricity during off peak hours when generation costs are low and generation assets are underutilized, which will increase their profits and save the consumer money. Additionally, shifting such power demands to night time use may help even out the demand for electrical power, when viewed from a 24 hour day perspective, which would tend to decrease the maximum system capacity needed. This, in turn, could lead to a lessened need for new electrical generation capacity.

In addition, there may be an additional road tax placed on electricity used to charge vehicles. This may extend to some form of “negative tax,” or tax credit, whereby operators of electric or electric-hybrid vehicles may receive an incentive for their use. In the event of government entities desiring to collect a road tax (or credit) on miles driven by an electric vehicle, the instant invention will be able to gather, store, and report vehicle charging energy consumption data on which the tax may be computed and levied.

### SUMMARY OF INVENTION

In its most general configuration, the present invention advances the state of the art with a variety of new capabilities and overcomes many of the shortcomings of prior devices in new and novel ways. In its most general sense, the present invention overcomes the shortcomings and limitations of the prior art in any of a number of generally effective configurations. The instant invention demonstrates such capabilities and overcomes many of the shortcomings of prior methods in new and novel ways.

The system works to allow a uniquely identifiable chargable vehicle destination (a vehicle having a uniquely government recorded vehicle identification number (VIN), or a uniquely identified battery, or some other discretely identifiable destination) to be charged during times when electrical usage rates set by a utility company are low (most likely, in off-peak demand hours) and grid demand is low. A core element of the system is a vehicle system meter (PLUG SMART PAL™). The independent vehicle system meter will have the ability to tie directly into an AMI (Advanced Metering Infrastructure) provided by the utility company, and/or communicate directly, including by means of a Mobile Metering Infrastructure (MMI), with the utility company or an independent service organization or other external entity, via one or several of the many available communication protocols, as well as store a significant amount of charging data.

The vehicle system meter has the ability to tie into an AMI or MMI from a utility or other outside source and receive pricing signals and demand response signals. The vehicle system meter may be connected to an internet enabled webserver that allows the user to configure charging strategies and timings of the vehicle system meter in specific and the system in general. The vehicle system meter can be configured to be either totally dependent on a connection with an AMI, or to be independent and act simply as a mobile meter to provide charging statistics for the vehicle. The vehicle system meter may also include communication with a GPS device for location and be provided with enough memory to maintain statistics about vehicle charging. The messages that the vehicle system meter sends back to the AMI or through the MMI may include, but are not limited to, such recorded parameters as Accumulative Power (power usage statistics accumulated over the vehicle lifetime or other predetermined time period); Current Power (power accumulated with a current charge period, or other predetermined period); Mileage (lifetime average mileage (LAM) associated with charging parameters); Vehicle/Battery Identification Number (identification of unique vehicle or battery identity); Time/Date Charging (temporal records regarding charging); and Location (where charging took place). One skilled in the art will realize that this is only a partial list of recordable parameters that may be measured and recorded by the vehicle system meter, and that virtually any other quantifiably or temporally identifiable event may be added to this list.

The vehicle system meter may meter the electricity used to charge the vehicle, store the information, may send the information to the AMI or MMI, and through the web browser, can display statistics about the charging. There is also an option for the vehicle system meter to send the information back to a consumer specific data system (PLUG SMART CLOUD™) where the customer will have a profile. The profile may contain vehicle information and customer requested information, such as money saved, gas mileage, and equivalent fuel consumption. The vehicle system meter may have sufficient memory to store a significant amount of charging data to be viewed, possibly on the device through a web application hosted by the Vehicle system meter. Since the vehicle system meter may be directly connected to the internet, such data (kWh, usage times, etc.) may be uploaded automatically to the consumer specific data system so that the owner can see his or her usage, to the Utility (so that the utility can charge special rates for electric vehicle charging), and/or to taxing entities (for use in assessing and determining use taxes), or any other outside reporting entity as may be desired.

Numerous variations, modifications, alternatives, and alterations of the various preferred embodiments, processes, and methods may be used alone or in combination with one another as will become more readily apparent to those with skill in the art, with reference to the following detailed description of the preferred embodiments and the accompanying figures and drawings.

### BRIEF DESCRIPTION OF THE DRAWINGS

Without limiting the scope of the present invention as claimed below and referring now to the drawings and figures, all shown not-to-scale:

FIG. 1 shows a pictorial schematic representation of the system (10), indicating the components of the power distribution system limb (12) and the components of the power consumption control and recordation limb (14) of the system (10);

FIG. 2 shows a pictorial schematic representation of an embodiment of the system (10);

FIG. 3 shows a pictorial schematic representation of another embodiment of the system (10);

FIG. 4 shows a pictorial schematic representation of another embodiment of the system (10);

FIG. 5 shows a pictorial schematic representation of another embodiment of the system (10);

FIG. 6 shows a schematic representation of the system (10);

FIG. 7 shows a schematic representation of a power distribution system limb (12) of the system (10); and

FIG. 8 shows a schematic representation of a power consumption control and recordation limb (14) of the system (10).

These drawings are provided to assist in the understanding of the exemplary embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity. Those of ordinary skill in the art will also appreciate that a range of alternative configurations have been omitted simply to improve the clarity and reduce the number of drawings.

### DETAILED DESCRIPTION OF THE INVENTION

The mobile intelligent metering and charging system (10) for charging uniquely identifiable chargable vehicle destinations and method for employing the system (10) of the instant invention enables a significant advance in the state of the art. The preferred embodiments of the device accomplish this by new and novel arrangements of elements and methods that are configured in unique and novel ways and which demonstrate previously unavailable but preferred and desirable capabilities. The detailed description set forth below in connection with the drawings is intended merely as a description of the present embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention.

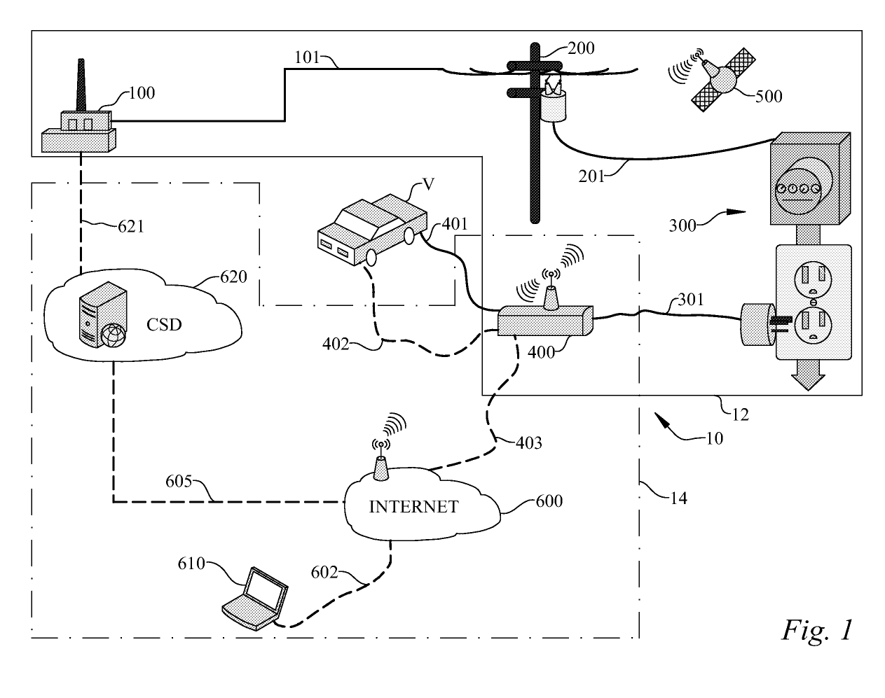

With regards to FIGS. 1-8, the system (10) includes such components as may be illustrated in the following examples.

### EXAMPLE 1

### Vehicle System Meter to Consumer Specific Data System

The first example illustrates a basic embodiment of the system (10), and may be seen illustrated in FIG. 1. Electrical power flows from a power source (100), in this case a utility, through a power source—point of distribution power transmission link (101) to a point of distribution means (200). In general, the point of distribution may represent the point at which the cost of electrical power is first identified and assigned to a specific customer. By way of example and not limitation, a point of distribution could represent a line drop from a utility pole to a particular residence or business location. The electrical power is then transmitted by means of a point of distribution means—point of service power transmission link (201) to a uniquely identifiable point of service (300). In general, the point of service may be the point at which users are able to access power delivered from a utility. Again, by way of example only and not limitation, a point of service could be an electrical outlet, most commonly connected to some sort of metering device, present in a power customer's home or business location.

The electrical power may then be transmitted by a point of service—vehicle system meter power transmission link (301) to a vehicle system meter (400), and then to a uniquely identifiable chargable vehicle destination (V) by means of a vehicle system meter—vehicle power transmission link (401). This completes a power distribution system limb (12) of the system (10). The vehicle system meter (400) may allow or not allow the charging of the uniquely identifiable chargable vehicle destination (V) based on a programmed algorithm taking into account numerous factors, including by way of example only, time of day, cost of power, charge status of uniquely identifiable chargable vehicle destination, and other numerous factors.

To facilitate the recording and reporting of power consumed, the uniquely identifiable chargable vehicle destination (V) may report its status back to the vehicle system meter (400) through a vehicle system meter—vehicle communication link (402). The vehicle system meter (400) may be in communication by means of a vehicle system meter—command and control system communication link (403) to a command and control system (600). In this example, the command and control system (600), which also in this example includes an ethernet link in communication with an internet enabled webserver, is in communication with a consumer specific data system (620) by means of a command and control system—consumer specific data system communication link (605). The consumer specific data system (620) thereby can relay charging and other data gathered by the vehicle system meter (400) to the power source (100), in this case an electric utility, through a consumer specific data system—power source communication link (621). The consumer specific data system (620) may also create and maintain a user profile stored in communication with a power consumption control and recordation limb (14). Such a user profile may include billing means and records in regard to the system, and may relay such information to any of a plurality of outside agencies, including among others the power source (100).

In such an example, the owner of the vehicle system meter (400) might log in through a consumer interface (610), in this example a web browser from a computer, and view his or her own uniquely identifiable chargable vehicle destination's (V) charging information that was captured by the vehicle system meter (400). An additional option of the vehicle system meter (400) could possibly contain a GPS (500), for location tracking and logging.

One skilled in the art will appreciate that in this example the components of the power distribution system limb (12) and the components of the power consumption control and recordation limb (14) of the system (10) have no particular spatial or geographic linkage; that is, other than the common interface between the limbs (12, 14) which occurs at the vehicle system meter (400), the limbs may be entirely separated or closely linked in space.

### EXAMPLE 2

### Vehicle System Meter to AMI Smart Meter and Consumer Specific Data System

By way of identification only, AMI is an acronym for the term “Advanced Metering Infrastructure,” which is known in the art to represent a means, generally deployed by a utility company, to serve as an automated communication infrastructure that allows the utility direct access to a customer's meter and/or area/region. With this direct access, the utility is able to implement demand response programs and also give real-time pricing signals and energy consumption set points to homes and businesses. The AMI allows two-way communications between the utility company and the meter.

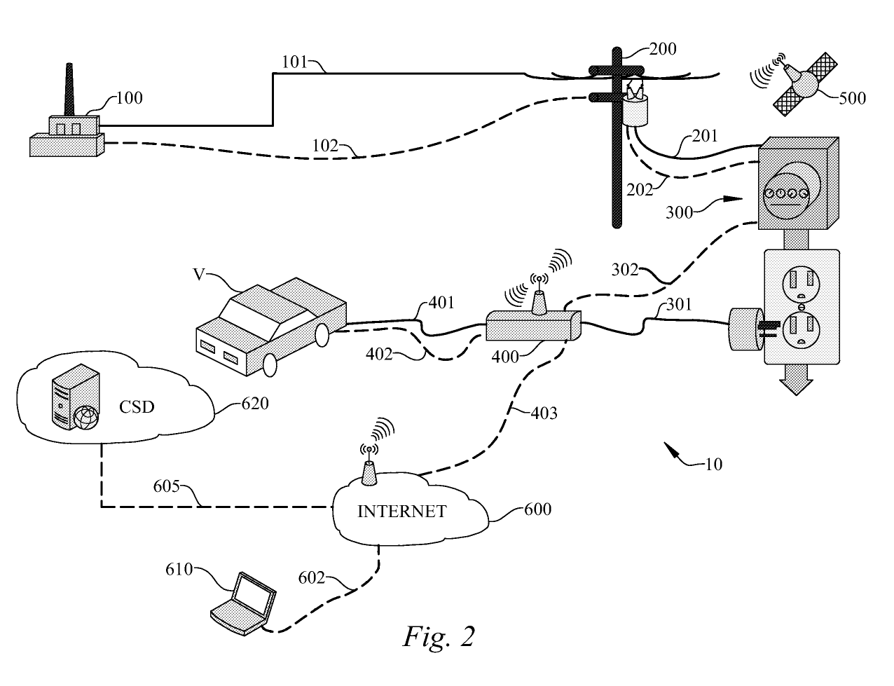

In this embodiment, seen illustrated in FIG. 2, the power distribution system limb (12) is similar to that as seen in Example 1, and the various structures may be exemplified as discussed above in Example 1. Electrical power flows from a power source (100), in this case a utility, through a power source—point of distribution power transmission link (101) to a point of distribution means (200). The electrical power is then transmitted by means of a point of distribution means—point of service power transmission link (201) to a uniquely identifiable point of service (300). The electrical power may then be transmitted by a point of service—vehicle system meter power transmission link (301) to the vehicle system meter (400), and then to the uniquely identifiable chargable vehicle destination (V) by means of a vehicle system meter —vehicle power transmission link (401). This completes a power distribution system limb (12) of the system (10).

However, in this example, the power consumption control and recordation limb (14) of the system (10) is handled through an AMI system. A vehicle system meter (400), running in conjunction with a command and control system (600) webserver, allows the vehicle system meter (400) to implement charging profiles and view statistics. Additionally, the vehicle system meter (400) may also communicate back to the power source (100), or to another entity, over a secure connection through the point of service (300), by means of a point of service—vehicle system meter communication link (302) and then to the point of distribution (200) by means of a point of distribution—point of service communication link (202), and from there, to the power source (100) by means of a power source—point of distribution communication link (102),

It is possible, as seen in this Example, for the command and control system (600), in this example an internet enabled Ethernet connection, to be in communication with the consumer specific data system (620), but not directly with the power source (100). Thus, such functions as billing could be handled completely apart from the power source (100). The consumer specific data system (620), in turn, can relay charging data gathered by the vehicle system meter (400) to create and maintain a user profile stored on an internet (600) enabled server, allowing the owner of the vehicle system meter (400) to log in through a web browser from a computer and view his or her own uniquely identifiable chargable vehicle destination's (V) charging information that was captured by the vehicle system meter (400). Again, an additional option of the vehicle system meter (400) could possibly contain a GPS (500), for location tracking and logging.

### EXAMPLE 3

### Vehicle System Meter to AMI UCM and Consumer Specific Data System

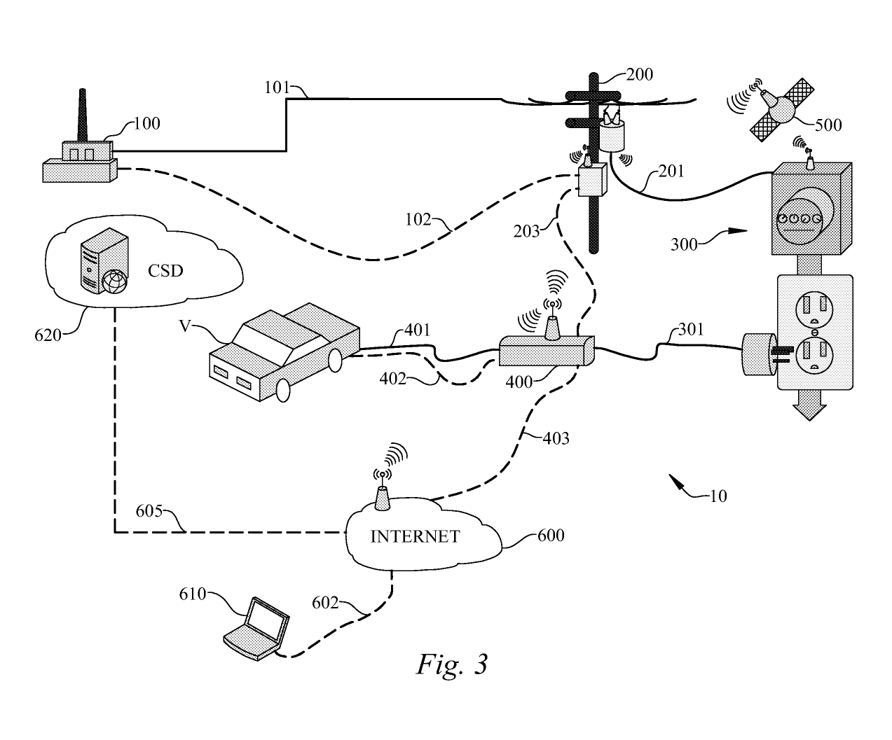

This embodiment illustrates a variation on the AMI system described in Example 2, and is seen illustrated in FIG. 3. The details of the power distribution system limb (12) remain unchanged. However, in the power consumption control and recordation limb (14) of the system (10), the vehicle system meter (400) communicates via AMI located on the point of distribution means (200) through a point of distribution—vehicle system meter communication link (203), rather than through the point of service—vehicle system meter communication link (302) and then to the point of distribution (200) by means of a point of distribution—point of service communication link (202) as previously described.

This embodiment describes a situation where the vehicle system meter (400), running an internet (600) enabled webserver that allows the owner of the vehicle system meter (400) to implement charging profiles and view statistics, communicates over a secure connection to a UCM (Universal Communication Module) belonging to a utility at the point of distribution (200) and also via Ethernet to the consumer specific data system (620). A uniquely identifiable chargable vehicle destination (V) could be charged with a vehicle system meter (400) at any point of distribution (200) where a UCM exists. The consumer specific data system (620) may, in turn, relay charging data gathered by the vehicle system meter (400) to a user profile stored on an internet server, exemplified by the command and control system (600), allowing the owner of the vehicle system meter (400) to log in through a web browser from a computer and view his or her own uniquely identifiable chargable vehicle destination's (V) charging information that had been captured by the vehicle system meter (400). As before, the embodiment could include a GPS (500), for location tracking and logging.

### EXAMPLE 4

### Vehicle System Meter to Mobile Metering Infrastructure (MMI) and Consumer Specific Data System

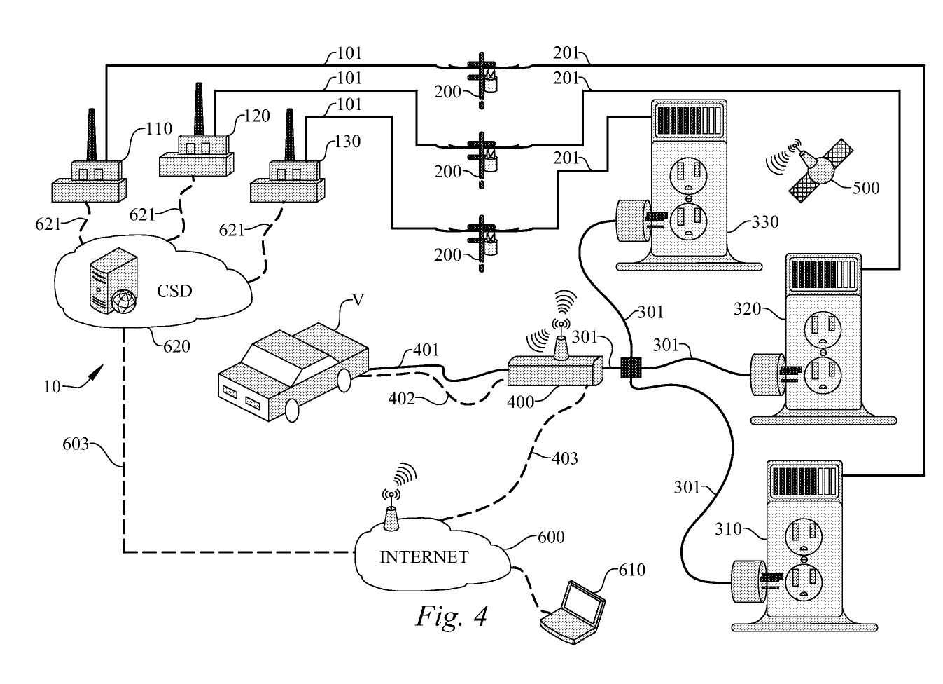

This embodiment, seen in FIG. 4, expands the flexibility of the system beyond that of Example 1, which contemplated a dedicated point of service (300) in the power transmission limb (10). In this embodiment, a mobile metering interface (MMI) allows charging anywhere the system (10) is configured for its use, without the need for any metering at the point of service (300). In addition, this embodiment illustrates the ability of the MMI system to detect and identify multiple power sources (110, 120, 130) and for the consumer specific data system (620) to differentiate and report to multiple power sources (110, 120, 130) based on such detection and identification.

As seen in FIG. 4, multiple power sources (110, 120, 130) transmit power via their respective power source—point of distribution power transmission links (101) through point of distribution (200) to multiple points of service (310, 320, 330). The vehicle system meter (400) has MMI capacity, and is able to detect and identify the individual point of service (310, 320, 330) to which it may be connected, and the associated multiple power sources (110, 120, 130) from which each may be receiving power through a point of service—vehicle system meter power transmission link (301).

As before, this describes, by way of example only, an example where a vehicle system meter (400), running an internet enabled webserver command and control system (600), may allow the owner of the vehicle system meter (400) to implement charging profiles and view statistics, to communicate over a secure connection over a Mobile Metering Infrastructure (MMI) defined by utilities and via Ethernet to the consumer specific data system (620). A uniquely identifiable chargable vehicle destination (V) may be charged anywhere an MMI exists. The consumer specific data system (620), in turn, may relay charging data gathered by the vehicle system meter (400) to a user profile stored on an internet enabled command and control system (600) server, allowing the owner of the vehicle system meter (400) to log in through a web browser from a computer and view his or her own uniquely identifiable chargable vehicle destination's (V) charging information that had been captured by the vehicle system meter (400). An additional option of the system (10) could possibly contain a GPS (500), for location tracking and logging.

### EXAMPLE 5

### Vehicle System Meter to Tax Entity and Consumer Specific Data System

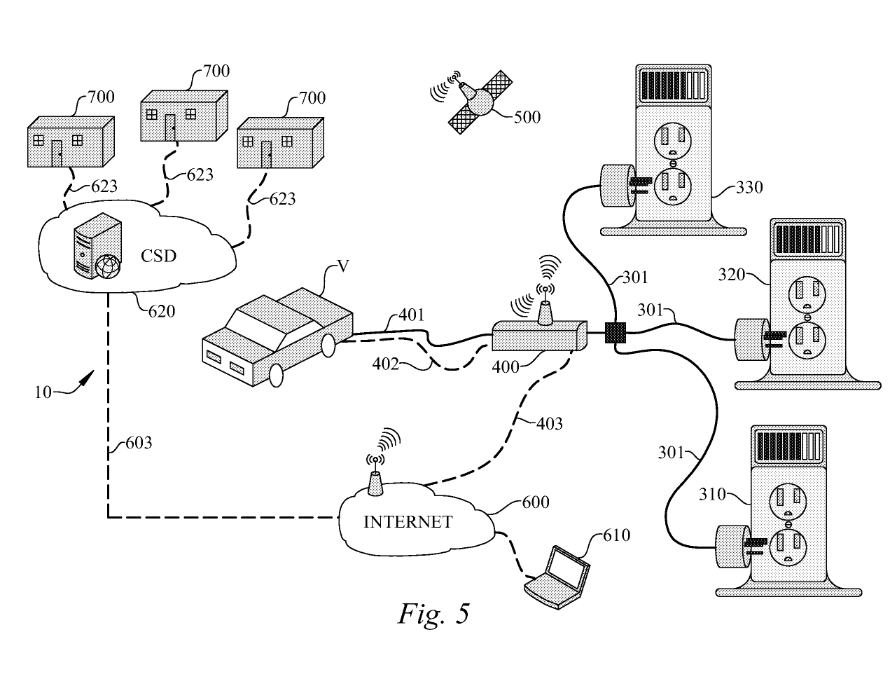

This embodiment, which may be seen illustrated at FIG. 5, illustrates a capacity of the vehicle system meter (400), running a webserver command and control system (600) and reporting to a consumer specific data system (620), which may, in addition or as an alternative to other functions described previously, in turn relay relevant information to external recording entities (700), including non-billing external recording entities (740). By way of example only, and not limitation, these external recording entities (700) may represent tax entities belonging to the government that could possibly manage road tax and special electric vehicle tax credits. A uniquely identifiable chargable vehicle destination (V) may be charged using the vehicle system meter (400) as described above, and the consumer specific data system (620) may also compile charging data gathered by the vehicle system meter (400) to a user profile stored on an internet (600) enabled server, allowing the owner of the vehicle system meter (400) to log in through a web browser from a computer and view his or her own uniquely identifiable chargable vehicle destination's (V) charging information that had been captured by the vehicle system meter (400). An additional option of the system (10) could possibly include a GPS (500), for location tracking and logging.

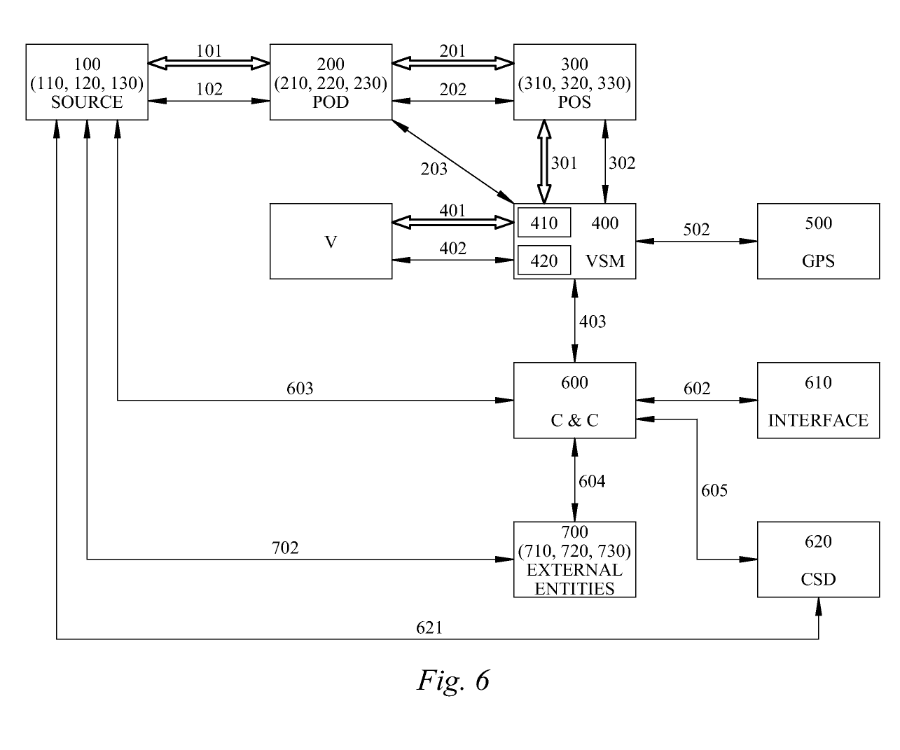

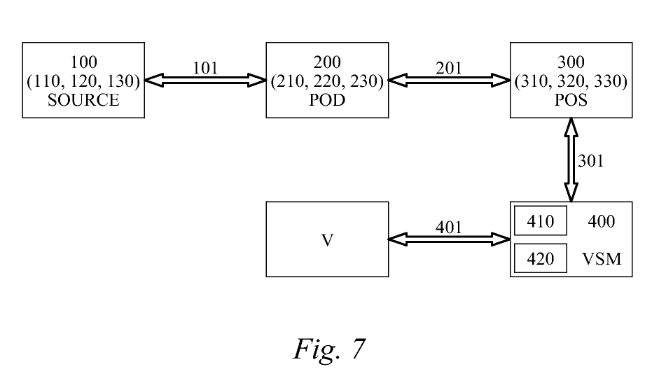

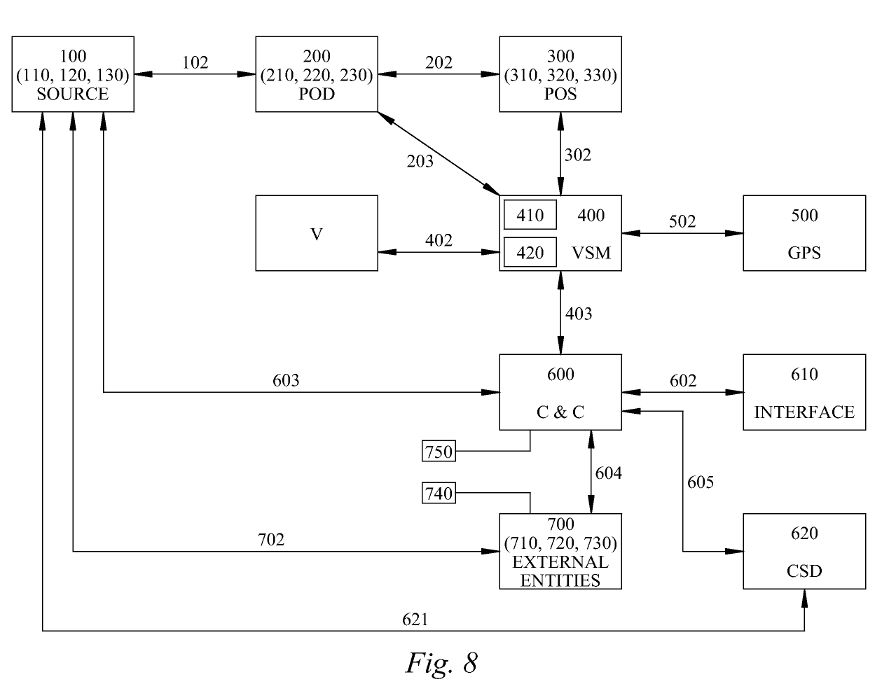

As seen in FIG. 6, the system (10) may be schematically represented, with one skilled in the art appreciating that all features present in such a schematic illustration need not be present in any specific embodiment. For sake of clarity, the schematic representation of the complete system (10) is separated into separate illustrations of the power distribution system limb (12) in FIG. 7 and the power consumption control and recordation limb (14) in FIG. 8.

What is claimed, then, as illustrated in FIGS. 1-8 is a mobile intelligent metering and charging system (10) for charging at least one uniquely identifiable chargable vehicle destination (V). The uniquely identifiable chargable vehicle destination (V) would commonly identify a unique vehicle associated with a uniquely government recorded vehicle identification number (VIN), but is also contemplated to include uniquely identifiable batteries. This would allow vehicles to use interchangeable batteries, and charging would be associated with the batteries, rather than with the vehicle.

The system (10) further includes at least two system limbs (12, 14) in communication with each other. There is a power distribution system limb (12), further having, in communication, at least one power source (100), at least one point of distribution means (200), at least one point of service (300), and at least one vehicle-system meter (400). The system (10), in particular, contemplates that all flows of power and communication are expressly intended to be bidirectional, so that the system (10) may operate, by way of example and not limitation only, to transmit power from the uniquely identifiable chargable vehicle destination (V) in a direction toward the power source (100) or any point in between. Therefore, again by way of example only, all terms such as “flows to/toward” “transmits to,” “to” or the like is expressly to be considered to envision and claim bidirectional movement of power and communication.

The system (10) also further includes a power consumption control and recordation limb (14), further having, in communication, at least one vehicle system meter (400), and at least one programmable command and control system (600). The vehicle system meter (400) further includes a memory module (410) reassignably associated with the at least one uniquely identifiable chargable vehicle destination (V), and a recording and reporting module (420) reassignably associated with at least one central billing station (750). The central billing station (750) would have access to and maintain at least one user account.

Both the programmable command and control system (600) and the vehicle system meter (400) are in communication with both the power distribution system limb (12) and the power consumption control and recordation limb (14). The programmable command and control system (600) controls the transmission of power through the vehicle system meter (400) according to a predetermined and programmable algorithm, resulting in charging of the uniquely identifiable chargable vehicle destination (V).

In other embodiments, the memory module (410) may reassignably store a plurality of the uniquely identifiable chargable vehicle destinations (V), and thus may be used with multiple vehicles, batteries, or other destinations.

In some embodiments, the command and control system (600) is in communication with the power source (100) by means of a power consumption control and recordation limb (14) that is associated with the power distribution system limb (12). This would commonly mean, by way of example only and not limitation, that the power consumption control and recordation limb (14) is in physical proximity to structural components of the power distribution limb (12) such as at least one of the points of distribution (200) and points of service (300). Alternatively, in other embodiments the command and control system (600) is in communication with the power source (100) by means of a power consumption control and recordation limb (14) independent of the point of service (300) and point of distribution (200). This would commonly mean, by way of example only and not limitation, that the power consumption control and recordation limb (14) is not in physical proximity to structural components of the power distribution system limb (12) such as at least one of the points of distribution (200) and points of service (300). In one particular embodiment, the power consumption control and recordation limb (14) is internet enabled.

In some embodiments, the vehicle system meter (400) is in communication with a Global Positioning System (GPS) (500) so that the uniquely identifiable chargable vehicle destination (V) may be geographically located and tracked.

In a favored embodiment, the programmable command and control system (600) further comprises a consumer interface (610) that further comprises programming means for programming the programmable command and control system (600). This allows the user, by way of example only and not limitation, to make a predetermined decision to charge or not charge a uniquely identifiable chargable vehicle destination (V) based on criteria such as time of day, cost of power, and other criteria that would be known to one skilled in the art. The system may also include a consumer specific data system (620) that may, again by way of example only and not limitation, record virtually any data associated with the charging of a uniquely identifiable chargable vehicle destination (V) and may store this information, identifiable with a particular user, or identifiable only as to aggregate users of the system (10).

The system (10) may also communicate with various external entities. In some embodiments, the system (10) further comprises at least one external recording entity (700), possibly including at least one non-billing external recording entity (740), in communication with the programmable command and control system (600). The non-billing external recording entity (740) receives information from the programmable command and control system (600). This would commonly be, by way of example only and not limitation, an agency, such as a government agency, that apart from any billing for electrical power function, may gather applicable information for the application of taxes or tax credits. Such non-billing external recording entities (740) may also gather and process information for such diverse uses as planning and predicting electrical power usage patterns, providing information to authorities, or for virtually any other reporting function.

The system (10), in some embodiments, could proactively aid users by identifying at least one preferred point of service (300) based on predetermined criteria and the geographic location of the at least one uniquely identifiable chargable vehicle destination (V) as determined by the GPS system (500). This could, by way of example only and not limitation, aid users in locating the most convenient and/or most inexpenseive sources of electrical power for charging. As would be known and expanded upon by one skilled in the art, this aid could be rendered by making recommendations based on predetermined criteria such as price of electrical power, geographic driving distance between the point of service (300) and the uniquely identifiable chargable vehicle destination (V), and availability status of at least one point of service (300).

The system (10) is therefore useful in accomplishing a method for charging at least one electric uniquely identifiable chargable vehicle destination (V). The method would begin with transmitting electrical power from a power source (100) to a uniquely identifiable chargable vehicle destination (V) through a power distribution system limb (12), and controlling and recording such power transmission through a power consumption control and recordation limb (14).

The step of transmitting could further include the steps of transmitting electrical power from the power source (100) through a power source—point of distribution power transmission link (101) to a point of distribution means (200). The electrical power could then be distributed from the point of distribution means (200) through a point of distribution—point of service power transmission link (201) to a point of service (300). The method would then allow for selecting a predetermined charging method according to programmable predetermined criteria.

Electrical power may then be distributed from the point of service (300) through a point of service—vehicle system meter power transmission link (301) to a vehicle system meter (400). From there, the electrical power may be distributed from the vehicle system meter (400) through a vehicle system meter—vehicle power transmission link (401) to the uniquely identifiable chargable vehicle destination (V).

The step of controlling and recording such power transmission may further include the steps of monitoring, controlling, and recording the distribution of electrical power through the vehicle system meter—vehicle power transmission link (401) to the uniquely identifiable chargable vehicle destination (V) according to a programmable predetermined algorithm.

In some embodiments, the method may further include the step of reporting the recorded distribution of electrical power to at least one central billing station (750). In yet other embodiments, the method may also include the step of reporting the recorded distribution of electrical power to at least one external recording entity (700), and may further include at least one non-billing external recording entity (740).

The method may allow changes in the programmable predetermined criteria to be made on a permanent or time-limited basis. For example, a user or user's agent may make permanent changes to the programmable predetermined algorithm, or may allow one-time, or other time limited changes or overrides to be allowed within the method.

Numerous alterations, modifications, and variations of the preferred embodiments disclosed herein will be apparent to those skilled in the art and they are all anticipated and contemplated to be within the spirit and scope of the instant invention. For example, although specific embodiments have been described in detail, those with skill in the art will understand that the preceding embodiments and variations can be modified to incorporate various types of substitute and or additional or alternative materials, relative arrangement of elements, and dimensional configurations. Accordingly, even though only few variations of the present invention are described herein, it is to be understood that the practice of such additional modifications and variations and the equivalents thereof, are within the spirit and scope of the invention as defined in the following claims. The corresponding structures, materials, acts, and equivalents of all means or step plus function elements in the claims below are intended to include any structure, material, or acts for performing the functions in combination with other claimed elements as specifically claimed.

We claim:

1. A mobile intelligent metering and charging system (10) for charging at least one uniquely identifiable chargable vehicle destination (V), comprising:
at least two system limbs (12, 14) in communication with each other, further comprising,
a power distribution system limb (12), further comprising in communication, at least one power source (100), at least one point of distribution means (200), at least one point of service (300), and at least one vehicle system meter (400);
a power consumption control and recordation limb (14), further comprising in communication, at least one vehicle system meter (400), and at least one programmable command and control system (600); wherein the vehicle system meter (400) further comprises a memory module (410) reassignably associated with the at least one uniquely identifiable chargable vehicle destination (V), and a recording and reporting module (420) reassignably associated with at least one central billing station (750) having at least one user account, and wherein,
both the at least one programmable command and control system (600) and the vehicle system meter (400) are in communication with both the power distribution system limb (12) and the power consumption control and recordation limb (14), and the at least one programmable command and control system (600) controls the transmission of power through the vehicle system meter (400) according to a predetermined and programmable algorithm, resulting in charging of the uniquely identifiable chargable vehicle destination (V).

2. The system (10) according to claim 1, wherein the memory module (410) reassignably stores a plurality of uniquely identifiable chargable vehicle destinations (V).

3. The system (10) according to claim 1, wherein the at least one programmable command and control system (600) is in communication with the power source (100) by means of a power consumption control and recordation limb (14) that is associated with at least one point of distribution (200).

4. The system (10) according to claim 1, wherein the at least one programmable command and control system (600) is in communication with the power source (100) by means of a power consumption control and recordation limb (14) independent of the point of service (300) and point of distribution (200).

5. The system (10) according to claim 1, wherein the vehicle system meter (400) is in communication with a Global Positioning System (GPS) (500).

6. The system (10) according to claim 1, wherein the at least one programmable command and control system (600) further comprises a consumer interface (610) that further comprises programming means for programming the at least one programmable command and control system (600).

7. The system (10) according to claim 1, wherein the at least one programmable command and control system (600) further comprises a consumer specific data system (620).

8. The system (10) according to claim 1, wherein the system further comprises at least one external recording entity (700) in communication with the at least one programmable command and control system (600), wherein the external recording entity (700) receives information from the at least one programmable command and control system (600).

9. The system (10) according to claim 5, wherein the system (10) identifies at least one preferred point of service (300) based on predetermined criteria and the geographic location of the at least one uniquely identifiable chargable vehicle destination (V) as determined by the GPS system (500).

10. The system (10) according to claim 9, wherein the predetermined criteria include at least one criteria selected from the group of criteria consisting of the price of electrical power, geographic driving distance between the point of service (300) and the uniquely identifiable chargable vehicle destination (V), and availability status of at least one point of service (300).

11. A mobile intelligent metering and charging system (10) for charging at least one uniquely identifiable chargable vehicle destination (V), comprising:
at least two system limbs (12, 14) in communication with each other, further comprising,
a power distribution system limb (12), further comprising in communication, at least one power source (100), at least one point of distribution means (200), at least one point of service (300), and at least one uniquely predetermined vehicle system meter (400);
a power consumption control and recordation limb (14) independent of the point of service (300) and point of distribution (200), further comprising in communication, at least one vehicle system meter (400), and at least one programmable command and control system (600); wherein the vehicle system meter (400) further comprises a memory module (410) reassignably associated with the at least one uniquely identifiable chargable vehicle destination (V), and a recording and reporting module (420) reassignably associated with at least one central billing station (750) having at least one user account, and wherein,
both the at least one programmable command and control system (600) and the vehicle system meter (400) are in communication with both the power distribution system limb (12) and the power consumption control and recordation limb (14), and the at least one programmable command and control system (600) controls the transmission of power through the vehicle system meter (400) according to a predetermined and programmable algorithm, resulting in charging of the uniquely identifiable chargable vehicle destination (V).

12. The system (10) according to claim 11, wherein the memory module (410) reassignably stores a plurality of the uniquely identifiable chargable vehicle destinations (V).

13. The system (10) according to claim 11, wherein the memory module (410) reassignably stores a plurality of uniquely identifiable user accounts.

14. The system (10) according to claim 11, wherein the at least one programmable command and control system (600) is in communication with the power source (100) by means of a power consumption control and recordation limb (14) independent of the point of service (300) and point of distribution (200).

15. The system (10) according to claim 11, wherein the at least one programmable command and control system (600) further comprises a consumer interface (610) that further comprises programming means for programming the at least one programmable command and control system (600).

16. The system (10) according to claim 11, wherein the at least one programmable command and control system (600) further comprises a consumer specific data system (620).

17. A method for charging at least one electric uniquely identifiable chargable vehicle destination (V) comprising:
transmitting electrical power from a power source (100) to a uniquely identifiable chargable vehicle destination (V) through a power distribution system limb (12), and controlling and recording such power transmission through a power consumption control and recordation limb (14), wherein the step of transmitting further comprises the steps of:
transmitting electrical power from the power source (100) through a power source—point of distribution power transmission link (101) to a point of distribution means (200);
distributing the electrical power from the point of distribution means (200) through a point of distribution—point of service power transmission link (201) to a point of service (300);
selecting a predetermined charging method according to programmable predetermined criteria;
distributing the electrical power from the point of service (300) through a point of service —vehicle system meter power transmission link (301) to a vehicle system meter (400);
distributing the electrical power from the vehicle system meter (400) through a vehicle system meter—vehicle power transmission link (401) to the uniquely identifiable chargable vehicle destination (V); and wherein,
controlling and recording such power transmission, further comprises the steps of,
monitoring, controlling, and recording the distribution of electrical power through the vehicle system meter—vehicle power transmission link (401) to the uniquely identifiable chargable vehicle destination (V) according to a programmable predetermined algorithm.

18. The method according to claim 17, further comprising the step of reporting the recorded distribution of electrical power to at least one central billing station (750).

19. The method according to claim 17, further comprising the step of reporting the recorded distribution of electrical power to at least one non-billing external recording entity (740).

20. The method according to claim 17, further comprising the step of allowing changes in the programmable predetermined criteria to be made on a permanent or time-limited basis.
